(19) United States
(12) Patent Application Publication
(10) Pub. No.: US 2010/0029047 A1
(43) Pub. Date: Feb. 4, 2010

(54) METHOD OF FABRICATING PRINTED CIRCUIT BOARD HAVING SEMICONDUCTOR COMPONENTS EMBEDDED THEREIN

(75) Inventors: Shih-Ping Hsu, Taoyuan (TW); Wei Che Lin, Taoyuan (TW)

Correspondence Address: EDWARDS ANGELL PALMER & DODGE LLP, P.O. BOX 55874, BOSTON, MA, 02205, US

(73) Assignee: PHOENIX PRECISION TECHNOLOGY CORPORATION, Hsin-Chu (TW)

(21) Appl. No.: 12/510,379

(22) Filed: Jul. 28, 2009

(30) Foreign Application Priority Data
Jul. 31, 2008 (TW) 097128944

(51) Int. Cl. H01L 21/52

(52) U.S. Cl. 438/126; 257/E21.5

(57) ABSTRACT

A method for fabricating a printed circuit board having semiconductor components embedded therein is provided. A carrier board having at least a predetermined hole area is provided. A plurality of through holes are formed in the surround of the predetermined hole area on the carrier board. A rectangular cavity is formed by punching to remove the predetermined hole area, and a plurality of through holes are formed around the rectangular cavity The through holes facilitate receipt of the semiconductor chip and filling of a fixing material in the rectangular cavity, to avoid displacement of the semiconductor chip in subsequent fabricating steps that would otherwise cause a drawback, that is, a wiring to be formed later is improperly electrically connected to the semiconductor chip.

### BACKGROUND OF THE INVENTION

1. Field of the Invention

The present invention relates to methods for fabricating semiconductor devices, and more particularly, to a method for fabricating a printed circuit board having semiconductor components embedded therein.

2. Description of the Prior Art

In addition to conventional semiconductor packaging technologies like wire bonding and flip-chip package, different packages are currently developed for semiconductor devices as the development of semiconductor packaging technologies focus more and more on high integration and multi-functionality. In the current semiconductor packaging technologies, a structure in which a semiconductor chip having an integrated circuit is embedded and electrically integrated in a packaging substrate and the packaging technology thereof are provided. Since the semiconductor chip is embedded in the packaging substrate, the height of the package can be lowered and an electric current path generated by electrical connections can be shortened to lower electrical resistance and subsequently increase conduction efficiency. Thus, the packaging technology has become a mainstream technology.

Referring to FIGS. 1A to 1D, a schematic diagram illustrating a method for fabricating a conventional packaging substrate having semiconductor chips embedded therein is provided, wherein FIG. 1A′ is a top view of the schematic diagram of FIG. 1A.

As shown in FIGS. 1A and 1A′, a first carrier board 11 is provided. The first carrier board 11 has a first surface 11a and a second surface 11b opposed to the first surface 11a, and at least a rectangular cavity 110 is formed in the first carrier board 11 to pass through the first surface 11a and the second surface 11b. At the same time, a second carrier board 12 is provided. The second carrier board 12 is disposed on the second surface 11b of the first carrier board 11 to cover one side of the rectangular cavity 110.

As shown in FIG. 1B, a semiconductor chip 13 is then provided. The semiconductor chip 13 has an active surface 13a and an inactive surface 13b. The active surface 13a has a plurality of electrode pads 131 thereon, and an adhesive layer 14 is used to fix the inactive surface 13b of the semiconductor chip 13 onto the second carrier board 12 exposed from the rectangular cavity 110.

As shown in FIG. 1C, a dielectric layer 15 is formed on the first carrier board 11 and the active surface 13a of the semiconductor chip 13 by thermocompression. Further, the dielectric layer 15 fills the gap between the rectangular cavity 110 and the semiconductor chip 13.

As shown in FIG. 1D, a wiring layer 16 is formed on the dielectric layer 15, and conductive vias 161 are formed in the dielectric layer 15 to allow the wiring layer 16 to be electrically connected to the electrodes pads 131 of the semiconductor chip 13.

However, it is necessary to preserve the gap between the semiconductor chip 13 and the rectangular cavity 110 beforehand. When the dielectric layer 15 is thermally compressed, factors like pressure, bubbling, etc. are likely to cause the semiconductor chip 13 to deviate by a distance e in the rectangular cavity 110 (as shown in FIG. 1C). The deviation prevents the conductive vias 161 from being in alignment with the electrode pads 131 and may, when overdone, even prevent the conductive vias 161 from being effectively electrically connected to the electrode pads 131.

Further, if the diameter of the rectangular cavity 110 is slightly larger than the outer diameter of the semiconductor chip 13, any attempt to put the semiconductor chip 13 in the rectangular cavity 110 is likely to end up damaging the semiconductor chip 13 upon collision between the semiconductor chip 13 and the edges of the rectangular cavity 110.

Therefore, in light of the aforesaid problems, it is imperative to avoid causing damage to a semiconductor chip when placing the semiconductor chip into the rectangular cavity, avoid the likely deviation of the semiconductor chip as the dielectric layer is formed on the semiconductor chip and the first carrier board by thermocompression, and avoid generating a deviation in position as the conductive vias are electrically connected to the electrode pads of the semiconductor chip which might otherwise be unable to be electrically connected to the electrode pads and thereby render the product defective and lower the yield.

### SUMMARY OF THE INVENTION

In light of the aforesaid drawbacks of the prior art, an objective of the present invention is to provide a method for fabricating a printed circuit board having semiconductor components embedded therein, and a printed circuit board structure capable of ensuring that semiconductor chips are easily received and fixed therein in subsequent fabricating steps.

Another objective of the present invention is to provide a method for fabricating a printed circuit board having semiconductor components embedded therein to thereby increase the conforming rate in wiring in subsequent fabricating steps.

In order to attain the aforesaid objectives, the present invention provides a method for fabricating a printed circuit board having semiconductor components embedded therein, comprising the steps of: providing a carrier board defined with at least a predetermined hole area; forming a plurality of through holes in the surround of the predetermined hole area on the carrier board; punching to remove the predetermined hole area of the carrier board to form a rectangular cavity; disposing a semiconductor chip in the rectangular cavity, the semiconductor chip having an active surface and an inactive surface opposed to the active surface, and the active surface having a plurality of electrode pads disposed thereon; filling a gap between the semiconductor chip and the rectangular cavity with a fixing material so as for the semiconductor chip to be fixed in position to the rectangular cavity; forming a first dielectric layer on the semiconductor chip, the fixing material and the carrier board, and forming a plurality of openings in the dielectric layer to expose each of the electrode pads; and forming a first wiring layer on the first dielectric layer, and forming a first conductive via in each of the openings in the dielectric layer to allow the first wiring layer to be electrically connected to each of the electrode pads of the semiconductor chip.

In light of the aforesaid method for fabricating a printed circuit board having semiconductor components embedded therein, the carrier board is an insulation board, a metal board or a wiring board obtained after completion of early stage wiring fabrication.

Further, the through holes are formed at the corners of the predetermined hole area; or the through holes are formed at midpoints of four edges of the predetermined hole area, respectively. The through holes are formed by mechanical drilling, laser drilling or punching.

In light of the above, a method for fabricating the first wiring layer includes the steps of: forming a conductive layer on the first dielectric layer, the inner walls of the openings in the dielectric layer and the electrode pads; forming a resist layer on the conductive layer, and forming a plurality of open areas in the resist layer to expose a portion of the conductive layer, wherein a portion of the open areas corresponds in position to each of the openings in the dielectric layer; and forming a first wiring layer in the open areas, and forming a first conductive via in each of the openings in the dielectric layer.

Moreover, a semiconductor chip is received in the rectangular cavity by mounting the carrier board on a release film, and mounting the semiconductor chip on the release film exposed from the rectangular cavity of the carrier board, and removing the release film. The method further includes the steps of: forming a build-up structure on the first dielectric layer and the first wiring layer, the build-up structure comprises at least a second dielectric layer, forming a second wiring layer on the second dielectric layer, and forming a plurality of second conductive vias in the second dielectric layer to electrically connect the first wiring layer and the second wiring layer, and forming a solder mask on the build-up structure, and forming a plurality of openings in the sold mask to expose each conductive pad of the second wiring layer, wherein the second wiring layer is outmost from the build-up structure.

In the method for fabricating a printed circuit board having semiconductor components embedded therein of the present invention, the steps of: forming a plurality of through holes in the surround of the predetermined hole area of the carrier board, punching to remove the predetermined hole area of the carrier board, and forming a rectangular cavity having a plurality of through holes disposed around it on the carrier board are first performed. In the subsequent steps of fabrication, the semiconductor chip is received in the rectangular cavity, and the fixing material fills a gap between the semiconductor chip and the rectangular cavity by being introduced to through holes and then being guided to the gap, so as to allow the semiconductor chip to be easily received and fixed in position to the rectangular cavity so as to avoid a drawback of the prior art, that is, the semiconductor chip deviates in subsequent steps and thus the first wiring layer to be formed later is not properly electrically connected to the semiconductor chip.

### BRIEF DESCRIPTION OF THE DRAWINGS

FIGS. 1A to 1D are schematic diagrams illustrating a method for fabricating a conventional packaging substrate having semiconductor chips embedded therein;

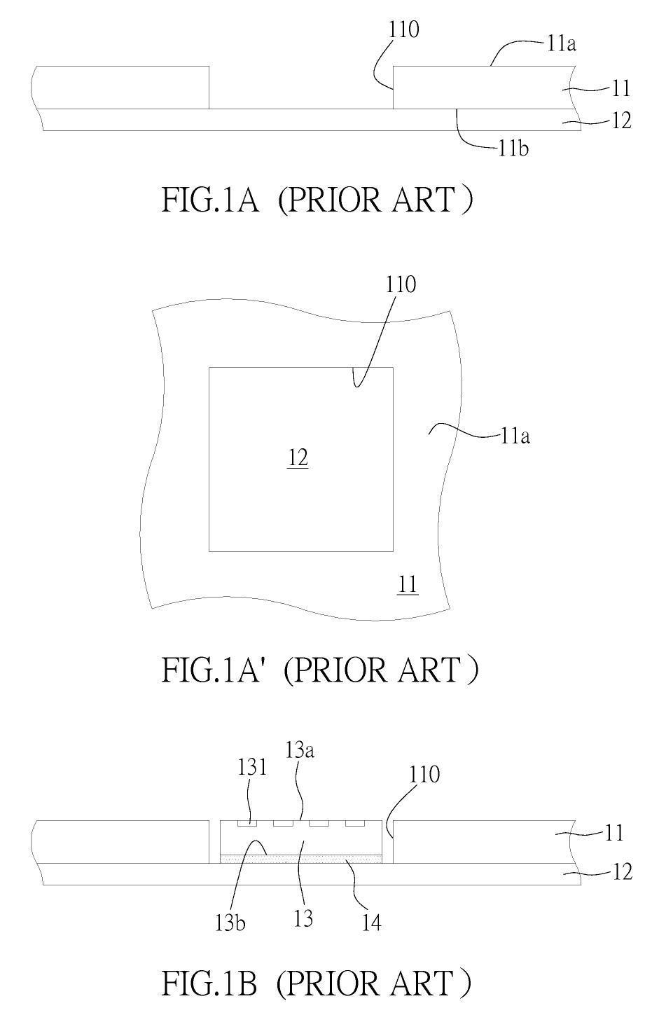

FIG. 1A′ is a top view of the schematic diagram of FIG. 1A;

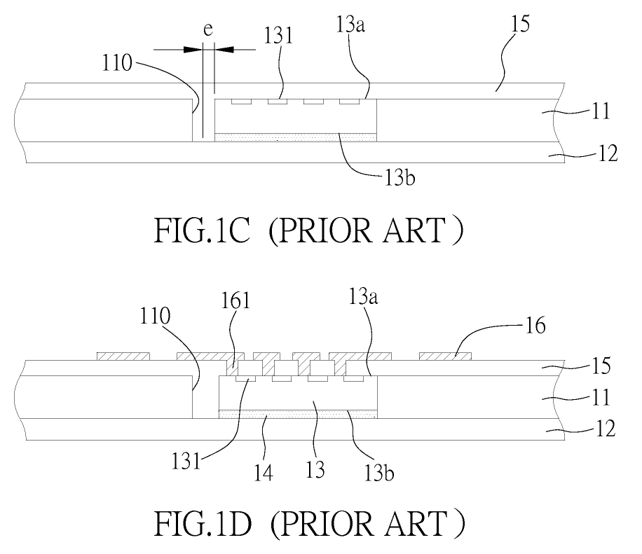

FIGS. 2A to 2C are top views illustrating the formation of a rectangular cavity in a carrier board by a method for fabricating a printed circuit board having semiconductor components embedded therein of the present invention;

FIG. 2C′ is a top view according to another embodiment of FIG. 2C;

FIG. 2C″ is a top view according to a further embodiment of FIG. 2C; and

FIGS. 3A to 3G are cross-sectional views illustrating a printed circuit boarding having semiconductor components embedded therein of the present invention.

### DETAILED DESCRIPTION OF THE INVENTION

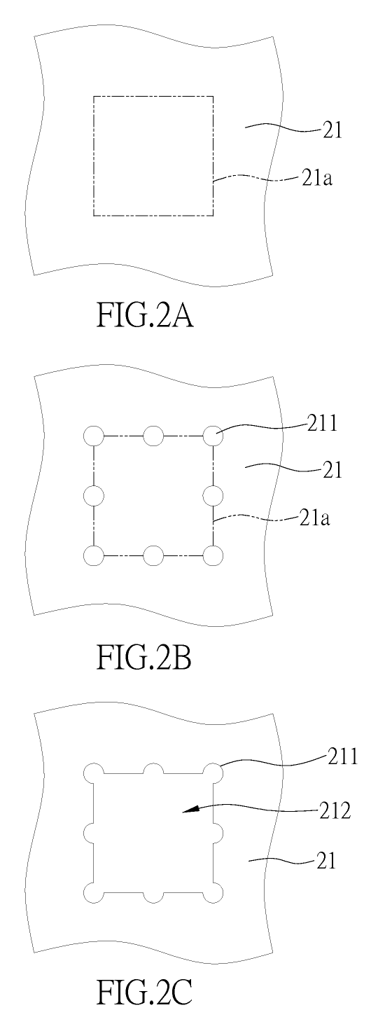

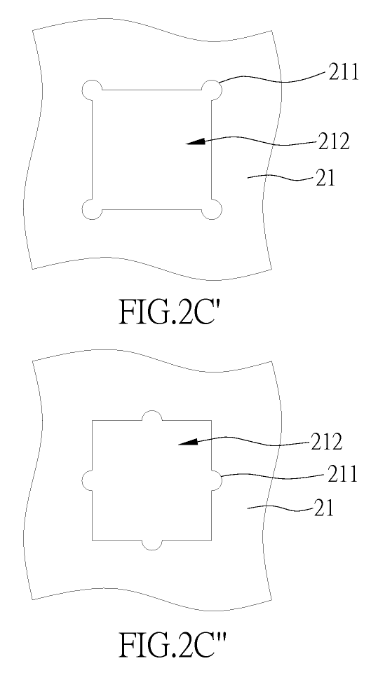

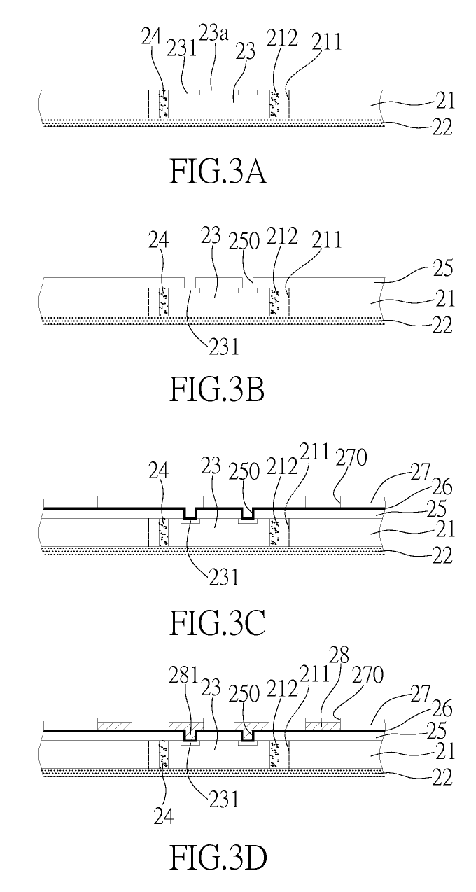

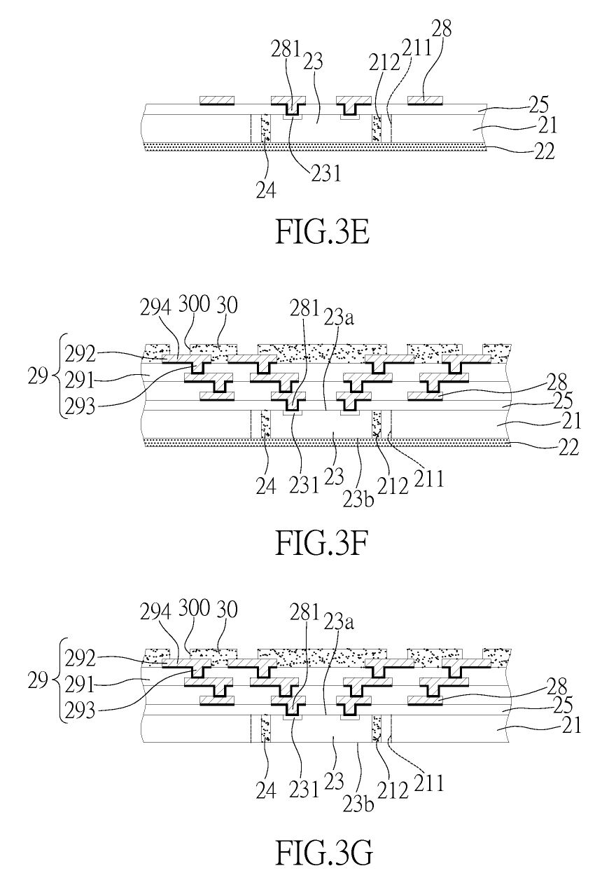

The following embodiments further illustrate the aspects of the present invention with reference to FIGS. 2 and 3, but none of the aspects are intended to limit the scope of the present invention.

### First Embodiment

Referring to FIGS. 2A to 2D, relevant schematic diagrams of a printed circuit board having embedded semiconductor components therein according to a first embodiment of the present invention are disclosed.

As shown in FIG. 2A, a carrier board 21 defined with at least a predetermined hole area 21a is provided. The carrier board 21 is an insulation board, a metal board or a wiring board obtained after completion of an early stage of wiring fabrication.

As shown in FIG. 2B, a plurality of through holes 211 are formed in the edges and at the corners of the predetermined hole area 21a of the carrier board 21 by mechanical drilling, laser drilling or punching.

### Second and Third Embodiments

As shown in FIGS. 2C to 2C″, a rectangular cavity 212 is formed in the carrier board 21 by punching to remove the predetermined hole area 21a (shown in FIG. 2C) of the carrier board 21; or the through holes 211 are formed at the corners of the predetermined hole area 21a, and the through holes 211 are formed at the corners of the rectangular cavity 212 (shown in FIG. 2 C′) after punching; or the through holes 211 are formed at midpoints of four edges of the predetermined hole area 21a, respectively, and the through holes 211 are formed on the four edges of the rectangular cavity 212 after punching (shown in FIG. 2C″). Further descriptions are based on the structure shown in FIG. 2C.

Referring to FIGS. 3A to 3G, the semiconductor chip is mounted on the carrier board, and the dielectric layer and the wiring layer are formed on the carrier board and the semiconductor chip.

As shown in FIG. 3A, the carrier board 21 having the rectangular cavity 212 is mounted on a release film 22, and then a semiconductor chip 23 is mounted on the release film 22 exposed from the rectangular cavity 212 of the carrier board 21 so as to allow the semiconductor chip 23 to be received in the rectangular cavity 212. The semiconductor chip 23 has an active surface 23a and an inactive surface 23b opposed to the active surface 23a, and the active surface 23a has a plurality of electrode pads 231 thereon. Then, a fixing material 24 fills a gap between the semiconductor chip 23 and the rectangular cavity 212, thereby allowing the semiconductor chip 23 to be fixed in position to the rectangular cavity 212. With the through holes 211 being formed at the corners of the rectangular cavity 212 or the four edges of the predetermined hole area 21a, the fixing material 24 fills the gap between the semiconductor chip 23 and the rectangular cavity 212 via the through holes 211 to avoid deviations of the semiconductor chip 23.

As shown in FIG. 3B, a first dielectric layer 25 is formed on the active surface 23a of the semiconductor chip 23, the fixing material 24 and the carrier board 21, and a plurality of openings 250 are formed in the first dielectric layer 25 to expose the electrode pads 231, respectively.

As shown in FIG. 3C, the method further comprises forming a conductive layer 26 on the first dielectric layer 25, inner walls of the openings 250, and the electrode pads 231, forming a resist layer 27 on the conductive layer 26, and forming a plurality of open areas 270 in the resist layer 27 to expose a portion of the conductive layer 26. A portion of the open areas 270 corresponds in position to each of the openings 250.

As shown in FIG. 3D, a first wiring layer 28 is formed in the open areas 270, and a first conductive via 281 is formed in each of the openings 250, so as allow the first wiring layer 28 to be electrically connected to each of the electrode pads 231 on the semiconductor chip 23.

As shown in FIG. 3E, the resist layer 27 and the portion of the conductive layer 26 covered thereby are removed to expose the first wiring layer 28 and the first dielectric layer 25.

As shown in FIG. 3F, a build-up structure 29 is formed on the first dielectric layer 25 and the first wiring layer 28. The build-up structure 29 comprises at least a second dielectric layer 291, a second wiring layer 292 formed on the second dielectric layer 291, and a plurality of second conductive vias 293 formed in the second dielectric layer 291 to electrically connect the first wiring layer 28 and the second wiring layer 29. The second wiring layer 292, which is outmost from the build-up structure 29, is provided with a plurality of conductive pads 294 thereon. A solder mask 30 is formed on the build-up layer 29, and a plurality of openings 300 are formed in the solder mask 30 to expose the conductive pads 294, respectively.

As shown in FIG. 3G, the release film 22 is removed to expose the inactive surface 23b of the semiconductor chip 23 and the carrier board 21.

In the method for fabricating a printed circuit board having semiconductor components embedded therein of the present invention, the steps of: forming a plurality of through holes in specific locations of a predetermined hole area of the carrier board, punching to remove the predetermined hole area of the carrier board, and forming a rectangular cavity having a plurality of through holes disposed around on the carrier board, receiving the semiconductor chip in the rectangular cavity, allowing a fixing material to fill a gap between the semiconductor chip and the rectangular cavity by being introduced to the through holes and then being guided to the gap, so as to allow the semiconductor chip to be easily received and fixed in position to the rectangular cavity so as to avoid a drawback of the prior art, that is, the semiconductor chip deviates in subsequent steps and thus the first wiring layer to be formed later is not properly electrically connected to the semiconductor chip.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for fabricating a printed circuit board having semiconductor components embedded therein, comprising the steps of:
providing a carrier board defined with at least a predetermined hole area;
forming a plurality of through holes in a surround of the predetermined hole area of the carrier board;
punching to remove the predetermined hole area of the carrier board so as to form a rectangular cavity;
receiving the semiconductor chip in the rectangular cavity, the semiconductor chip having an active surface and an inactive surface opposed to the active surface, and the active surface having a plurality of electrode pads disposed thereon;
filling a gap between the semiconductor chip and the rectangular cavity with a fixing material, thereby allowing the semiconductor chip to be fixed in position to the rectangular cavity;
forming a first dielectric layer on the semiconductor chip, the fixing material and the carrier board, and forming a plurality of openings in the first dielectric layer to expose the electrode pads, respectively; and
forming a first wiring layer on the first dielectric layer, and forming a first conductive via in each of the openings to electrically connect the first wiring layer to each of the electrode pads.

2. The method of claim 1, wherein the carrier board is one of an insulation board, a metal board and a wiring board obtained by completing an early stage of wiring fabrication.

3. The method of claim 1, wherein the through holes are formed at corners of the predetermined hole area.

4. The method of claim 1, wherein the through holes are formed at midpoints of four edges of the predetermined hole area, respectively.

5. The method of claim 1, wherein the through holes are formed by one of mechanical drilling, laser drilling and punching.

6. The method of claim 1, wherein the step of forming a first wiring layer further comprises the steps of:
forming a conductive layer on the first dielectric layer, inner walls of the openings in the dielectric layer and the electrode pads;
forming a resist layer on the conductive layer, and forming a plurality of open areas in the resist layer to expose a portion of the conductive layer, wherein a portion of the open areas corresponds in position to each of the openings in the dielectric layer; and
forming a first wiring layer in the open areas, and forming a first conductive via in each of the openings in the dielectric layer.

7. The method of claim 6, further comprising the steps of: receiving a semiconductor chip in the rectangular cavity, mounting the carrier board on a release film, and mounting the semiconductor chip on the release film exposed from the rectangular cavity of the carrier board.

8. The method of claim 7, further comprising the step of forming a build-up structure on the first dielectric layer and the first wiring layer.

9. The method of claim 8, wherein the build-up layer at least comprises a second dielectric layer, a second wiring layer formed on the second dielectric layer, a plurality of second conductive vias formed in the second dielectric layer to electrically connect the first wiring layer and the second wiring layer, the second wiring layer being outmost from the build-up structure and being provided with a plurality of conductive pads thereon.

10. The method of claim 9, further comprising the steps of: forming a solder mask on the build-up structure, and forming a plurality of openings in the solder mask to expose the conductive pads, respectively.

11. The method of claim 9, further comprising the step of removing the release film.
